(19) United States
(12) Patent Application Publication
(10) Pub. No.: US 2025/0169204 A1
(43) Pub. Date: May 22, 2025

(54) Method for Producing a UVC Imaging System Based on a Focal Plane Array of Metal-Semiconductor-Metal Photodetectors Using an Aluminum Alloy with Gallium Oxide

(71) Applicants: David J. ROGERS, Sainte Savine (FR); Ferechteh Henri HOSSEINI TEHERANI, Orsay (FR); Vinod Eric SANDANA, Garges-Lès-Gonesse (FR)

(72) Inventors: David J. ROGERS, Sainte Savine (FR); Ferechteh Henri HOSSEINI TEHERANI, Orsay (FR); Vinod Eric SANDANA, Garges-Lès-Gonesse (FR)

(21) Appl. No.: 18/929,601

(22) Filed: Oct. 28, 2024

(30) Foreign Application Priority Data
Oct. 27, 2023 (FR) FR2311773

(51) Int. Cl. H10F 30/227; H10F 39/12; H10F 39/18; H10F 77/12; H10F 77/162; H10F 77/20

(52) U.S. Cl. CPC H10F 30/2275; H10F 39/18; H10F 77/12; H10F 77/162; H10F 77/206; H10F 39/199

(57) ABSTRACT

A UVC Metal-Semiconductor-Metal photodetector with metallic contacts made of Ni and/or Au and/or Ti, characterized in that the photodetector comprises an aluminum alloy with Ga2O3, providing a broadened and/or shifted spectral response toward shorter wavelengths compared to a Ga2O3-only based detector. The invention also relates to an imaging system based on a UVC focal plane array with a network of MSM photodetectors with metallic contacts made of Ni and/or Au and/or Ti, based on (Al)Ga2O3, for remote detection/location/optical imaging of a fire, corona discharge, missile launch, ozone hole monitoring, or gas detection. The invention also relates to MSM UVC photodetectors designed on a substrate that is transparent in the UVC, allowing back-illumination to facilitate the manufacturing of flip-chip devices with higher efficiency compared to front-illuminated detectors by avoiding light reflections from the front surface metallic contacts.

### TECHNICAL FIELD OF THE INVENTION

This invention proposes a method for developing a new optical imaging array in the UVC spectrum.

Among its many potential applications, this imaging system could more quickly locate the starting points of fires.

There is an urgent need for better long-distance optical detection to more rapidly identify and extinguish fires that ravage our planet. Since infrared detectors are prone to false alarms caused by surrounding heat sources, optical fire sensors typically use sun-coupled sensors that are not subject to such parasitic signals. These mainly consist of vacuum tube photomultipliers (PMs), which are highly sensitive but bulky, fragile, expensive, and require high-voltage operation.

So far, semiconductor-based sensors have not been able to replace PMs because none of the current commercial options are inherently insensitive to the sun. GaN requires an aluminum alloy, and Si & SiC require filters, which result in low efficiency and the need for preamplifiers and/or high-voltage avalanche operation.

Recently, the inventors of the present invention developed revolutionary UVC sensors, launched during a French cubesat mission in April 2023 [1, 3, 6-8, 11]. Based on a next-generation semiconductor, Ga2O3, these sensors exhibit intrinsic solar insensitivity and strong spectral response. Consequently, they do not require solar filters, preamplifiers, or high operating voltages, significantly reducing mass, size, and cost compared to PMs. During qualification tests for use on small satellites, these sensors were also found to be highly resistant to heat, cold, vibrations, and radiation.

### PRIOR ART

DUV (Deep Ultraviolet) detection systems have garnered great interest in recent years due to their wide range of potential applications, including chemical analysis, UV lamp sterilization monitoring, high-temperature flame detectors, and receivers for ultraviolet communication, among others. Some of these applications, including high-temperature flame detectors and ultraviolet communication receivers, show virtually no noise caused by solar radiation, as most DUV radiation is absorbed by the ozone layer (Ref: Avila-Avendano et al., in “Deep UV Sensors Enabling Solar-Blind Flame Detectors for Large-Area Applications” (IEEE Sensors Journal, 21, 13 (2021) 14815)).

Conventional materials used in DUV detection systems include ultrawide bandgap (UWBG) semiconductors, with a bandgap (Eg) much larger than the 3.4 eV of gallium nitride (GaN), such as gallium oxide (Ga2O3) (Eg 4.9 eV), boron nitride, and diamond. These materials enable the fabrication of solar-blind DUV sensors with sensitivity values up to 1.3×10³ A/W for a ZnO/Ga₂O₃ micropoint avalanche photodetector (APD). Integrating DUV detection systems with low-cost, large-area compatible circuit technologies is necessary to enable broader applications. An example is the focal plane array (FPA) for solar-blind DUV imagers, which has only been realized using multilayer AlₓGa₁₋ₓN P-I-N photodiodes, discretely packaged and connected to commercially available CMOS readout integrated circuits. This approach relies on high-end processes that are not compatible with large-area or low-cost applications.

Further technological advancements are needed to make UV detection technologies compatible with large-area, low-cost flame detection applications. Flame detectors require a high DUV/visible rejection ratio (RR) to avoid false alarms, as most of these detectors operate under artificial or natural lighting conditions. Currently, photomultiplier tubes are the most commonly used devices for UVC flame detection. However, these devices are fragile, costly, bulky, difficult to scale, and require high operating voltages.

To address some of these technological bottlenecks, UWBG (ultrawide bandgap) semiconductor-based flame detectors are being studied as alternatives. For instance, AlGaN P-I-N photodiodes on sapphire, fabricated through lateral epitaxial overgrowth, have been demonstrated as flame detectors with a sensitivity of 0.1 A/W at a wavelength of 270 nm. Additionally, Schottky photodiodes based on single-crystal gallium oxide, grown using the float zone method (FZ), have also been demonstrated for flame detection applications. This photodetector exhibited a sensitivity of 37×10³ A/W at a wavelength of 250 nm. Flame detection was demonstrated when the device was connected to a commercial amplifier based on conventional CMOS electronics. Although these devices have shown flame detection capabilities using UWBG semiconductors, they are not compatible with large-area, low-cost applications due to the use of high-temperature growth methods that are incompatible with the CMOS electronics conventionally used for signal amplification.

In a rapidly growing UV sensor market, projected to reach $2.7 billion by 2024, UWBG semiconductor-based detectors have found little application in real-world systems and UV imaging technologies (e.g., on spacecraft or for flame detection) (Ref.: Kalra et al., “The road ahead for ultrawide bandgap solar-blind UV photodetectors” (J. Appl. Phys. 131, 150901 (2022)). Indeed, UV imagers based on CCD and CMOS dominate this market, despite their complexities related to additional filters, reduced efficiency, and weight. Research on UWBG UV detectors has so far remained mostly confined to academia.

Although there is a substantial amount of literature on all aspects of material growth and device development for UWBG photodetectors, studies on focal plane arrays (FPA) and their integration with readout integrated circuits (RoIC) have been relatively underexplored. There are even fewer reports on the investigation of reliability and yield, aging/wear testing, radiation resistance, and failure mechanisms for these device technologies. This gap in the literature presents a significant barrier to the commercial and strategic implementation of real-world systems using UWBG-based deep DUV sensors for imaging. Furthermore, while AlGaN/GaN HEMTs are rapidly entering the market for other applications, the strategic sector of deep UV AlGaN detectors remains confined to academic research. Since the aluminum content in AlGaN can be modulated to adjust the bandgap and, consequently, the cutoff wavelength between 200 and 365 nm, there are several studies demonstrating UVB detectors based on AlGaN as well. However, for solar-blind detection (<290 nm), the aluminum content in AlGaN must be at least 40%, which poses several challenges from a material development perspective. The epitaxy of AlGaN with a high aluminum content (>40%) is itself non-trivial in terms of controlling background impurity concentrations, doping, stress, dislocation densities, and other defects such as V-pits, all of which significantly affect device performance.

Moreover, p-type doping continues to represent a significant technological challenge, as the ionization energy of Mg (the most commonly used p-type dopant) is quite high for AlGaN. In fact, even the study and development of highly conductive n-type AlGaN with high aluminum content remains an important area of ongoing research.

For solar-blind UV detectors, sapphire is more commonly used than other substrates due to its transparency to deep UV light (>190 nm), allowing for back-side illumination of the devices, which is necessary for FPAs (focal plane arrays) in flip-chip configuration. Sapphire's lower cost (compared to SiC and AlN), a good lattice match with AlGaN, excellent growth control, and scalability further favor its selection. In addition to what has been reported in previous reviews, the authors (David, Rogers, et al., Proc. of SPIE Vol. 12422 (2023) 07-1) demonstrated in 2023 excellent results on yield, reliability, robustness, stability, aging/weather testing, and failure mechanisms for discrete UVC Ga2O3 photodetectors. Subsequently, these sensors achieved TRL9 technological maturity (and radiation resistance) during their successful deployment in space aboard a cubesat mission in April 2023. To our knowledge, this is the first TRL9 deployment of Ga2O3 photodetectors in a real-world application.

This invention relates to the development of a Ga2O3-based UVC focal plane array for optical fire detection/localization. It proposes operation without filters or pre-amplification, with an optimized peak response and bandwidth for fire detection. Optical, electronic, and image processing solutions will enable the exploitation of extreme sensitivity. Comparable UVC imaging arrays are not commercially available, and they will enable a range of space and terrestrial applications, such as UV astronomy, missile launch detection/localization, free-space gas detection/localization, and various inspection systems.

### SUMMARY OF THE INVENTION

This invention relates to a method for manufacturing a UVC imaging system for, for example, optical detection/localization of fire outbreaks.

The invention proposes a UVC metal-semiconductor-metal (MSM) photodetector focal plane array with metal contacts made of Ni and/or Au and/or Ti, characterized by an aluminum alloy with Ga2O3 that provides an expanded and/or blue-shifted spectral response compared to a Ga2O3-only detector.

Furthermore, this MSM UVC photodetector with Ni and/or Au and/or Ti metal contacts is designed to have partially Schottky and partially ohmic contacts, to both trap charge holes at the metal-semiconductor interface (to increase gain) and also to benefit from a low dark signal, fast response, and high photoconductive gain.

Additionally, the above MSM UVC photodetector array is fabricated on a substrate transparent to UVC light (e.g., sapphire or quartz) to allow for back-side illumination and the fabrication of flip-chip devices. This increases photodetector efficiency by eliminating light reflection from the metal contacts, which is responsible for reduced efficiency when illumination comes from the front side.

According to the features of the invention, the (Al)Ga2O3-based MSM UVC photodetectors have a decreasing aluminum concentration gradient during growth (through deposition conditions), which allows for capturing a broader spectrum of UVC light.

This result can be achieved through several approaches. For example, during growth, by modulating the concentration of the elements used (a gradient created by deposition conditions such as varying aluminum flux during molecular beam epitaxy, aluminum precursor flux during chemical vapor deposition (CVD), a different aluminum rate in targets used for physical vapor deposition (sputtering, ion beam deposition), or by laser ablation (pulse laser deposition), or atomic layer deposition). Another example involves post-growth thermal treatment or high deposition/annealing temperature to promote aluminum diffusion from the Al2O3 (sapphire) substrate. Another approach would be to use an aluminum-rich underlayer (such as Al2O3 or Al—O or Al—Ga—N) on a UV-transparent substrate other than sapphire. Yet another approach would be a mechanical stacking of atomic sheets with different concentrations.

The invention also relates to a flip-chip MSM UVC photodetector, based on a thin (between 2 nanometers and 1 micron thick) (Al)Ga2O3 layer with a decreasing aluminum gradient through its thickness, due to the material growth conditions and/or post-growth thermal treatment, which allows less deep UVC light to travel further into the layer to reach closer to the upper surface (where the metal contacts are located), thereby providing a broader wavelength detection window and thus more efficient and comprehensive UVC detection.

The invention also relates to an imaging system based on a UVC focal plane array composed of a network of MSM photodetectors made of (Al)Ga2O3 for remote optical fire detection/localization/imaging, corona discharge, missile launch detection, flash detonation, ozone layer hole monitoring, and gas detection.

### BRIEF DESCRIPTION OF THE FIGURES

FIG. 1 illustrates MSM photodetectors with interdigitated transducers (IDTs) fabricated on transparent sapphire substrates;

FIG. 2 shows the flip-chip bump bonding of the array;

FIG. 3 shows the uncalibrated composition profile of gallium and aluminum for a Ga2O3 layer grown on a sapphire substrate;

FIG. 4 is a schematic of the proposed detector structure and system architecture.

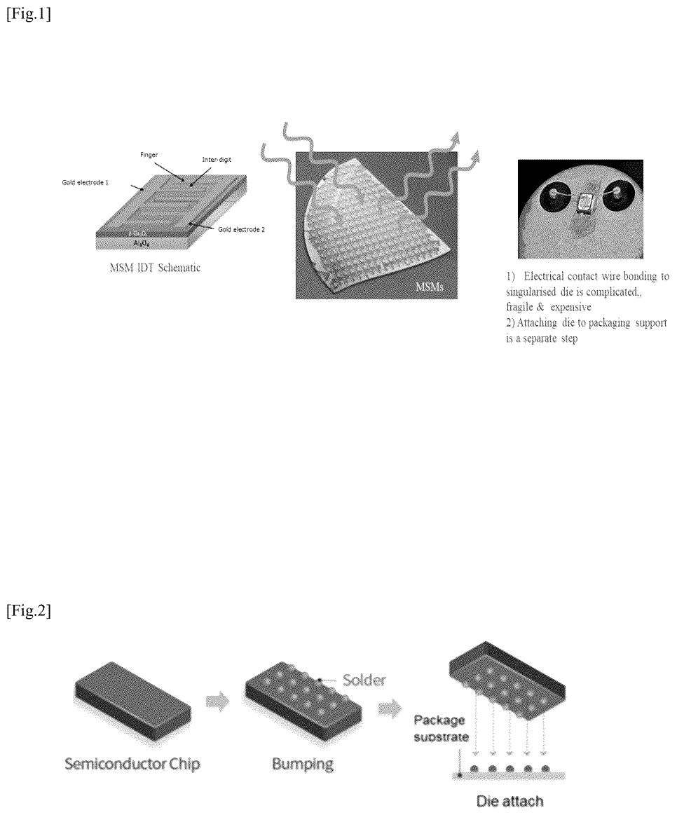

### DETAILED DESCRIPTION OF THE DRAWINGS

FIG. 2 shows: 1) electrical contact to the individualized chip, made via contact pads (e.g., In/Au electric) on the front metal electrode, followed by chip flipping before bonding to the base. In this case, light passes through the transparent substrate, eliminating reflection losses caused by metal electrodes. This process is simpler and more robust than front-side illumination and wire bonding, and it does not require expensive wire bonding equipment. 2) The attachment of the chip to a packaging support is already part of the process, thus reducing the number of process steps.

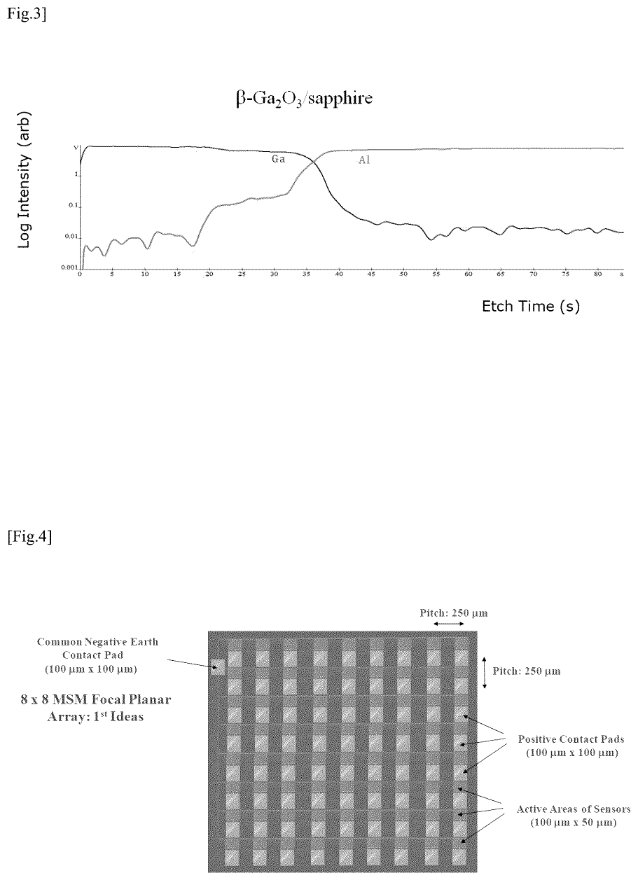

FIG. 3 presents depth profiles obtained by glow discharge mass spectrometry (GDMS) for Ga2O3 grown on sapphire at high temperature. The graph shows significant diffusion of aluminum from the substrate into the Ga2O3 layer, increasing the bandgap width near the substrate.

### DETAILED DESCRIPTION OF THE INVENTION

The purpose of the present invention is to construct an optical imaging system in the UVC range (which could, for example, be used for the early detection/location of fires on Earth from low Earth orbit).

The system is based on a focal plane array (FPA) of innovative UVC sensors made from (Al)Ga2O3. Such individual sensors were successfully tested for a French cubesat mission aimed at measuring Earth's radiation budget (“INSPIRESAT 7” launched with Space X in April 2023) [1, 3, 6-8, 11].

A second innovative aspect is designing detectors with increased gain/efficiency and panchromatic response (in the UVC) to maximize sensitivity and enable the miniaturization of the FPA.

A third innovative aspect is incorporating a novel flip-chip hybridization to maximize the signal (eliminating contact reflection losses), simplify manufacturing, and strengthen the system (no fragile wire bonding).

A fourth innovative aspect is developing suitable UV optics for maximum coupling and precise positioning of light.

Better remote optical detection is urgently needed to locate and extinguish fires that ravage our planet. Given that infrared detectors are subject to false signals from surrounding heat sources, optical fire sensors are generally coupled with UVC sensors (insensitive to solar radiation) that are not prone to such false alarms. Comparable UVC imaging arrays are not present in academic literature and are not commercially available. They will open up numerous possibilities for space and terrestrial applications, such as UV astronomy, missile launch detection/location, free-path gas detection/location, and various inspection systems.

The technical and functional requirements here concern the ability to create a compact UVC imaging array with a good solar rejection ratio, high robustness, and a reasonable refresh time (in the millisecond range).

Furthermore, interface requirements include: (a) a new flip-chip bonding to a commercial imaging integrated circuit, and (b) electronic and software interfaces with the ROIC.

Additionally, environmental requirements focus on minimizing the use of toxic or critical materials in the manufacturing/operation of components.

The user benefit is that there is currently no good commercial solution for UVC imaging. This breakthrough technology would enable the development of numerous important applications, such as UV astronomy, missile launch detection/location, free-path gas detection/location, flame/furnace monitoring, non-line-of-sight communications, corona detection, and various inspection systems.

In particular, the potential societal impact of reducing fire damage (through earlier detection/extinguishing) is quite dramatic in terms of lost forests, destroyed farmland, burned homes and infrastructure, and the reduction of greenhouse gas emissions (it is now acknowledged that wildfires produce an amount of greenhouse gases comparable to that emitted by all the world's vehicles).

### REFERENCES

Dynamical properties and performances of β-Ga2O3 UVC photodetectors of extreme solar blindness: L. Damé, L. Conan, C. De Santi, A. Caria, M. Buffolo, M. Meneghini, P. Maso, C. Dias, H. Ghorbel, P. Gilbert, M. Meftah, P. Bove, V. Sandana, D. Rogers, F. Teherani Proc. of SPIE Vol. 12422 (2023) 07-1.

Investigation of Enhanced Heteroepitaxy and Electrical Properties in Kappa-Ga2O3 due to Interfacing with β-Ga2O3 Template Layers J. Lee, L. Gautam, F. H. Teherani, E. V. Sandana, P. Bove, D. J. Rogers and M.Razeghi Phys. Stat. Solidi. a (2023) 2200559.

Realization, Calibrations and Spatialization n of β-(Al) Ga2O3 UVC Photodetectors of Extreme Solar Blindness for Space Observations L. Damé, P. Maso, L. Conan, C. Dias, H. Ghorbel, P. Gilbert, M. Meftah, D. Bolsée, N. Pereira, A. Caria, C. De Santi, M. Buffolo, M. Meneghini, P. Bove, V. Sandana, D. Rogers and F. Teherani; Proc. of 8th International Conference on Sensors Engineering & Electronics Instrumentation Advances, Corfu (2022).

Effect of high-energy electron irradiation on the electronic properties of beta gallium oxide; T.-H. Dang, M. Konczykowski, V. I. Safarov, E. Hammou, L. R. Vega, N. Ollier, R. Grasset, A. Alessi, H.-J. Drouhin, H. Jaffrès, V. Y. Davydov, A. Wołoś, D. J. Rogers, V.E. Sandana, P. Bove, F. H. Teherani; 07-1 (2022) 12002 Proc. of SPIE.

Microstrip Array Ring FETs with 2D p-Ga2O3 Channels grown by MOCVD M. Razeghi, J. Lee, L. Gautam, J.-P. Leburton, F. H. Teherani, P. K. Amiri, M.Grayson, V. P. Dravid & D. Pavlidis Photonics 8 (2021) 578.

Preparation & Characterization of β-Ga2O3-based Photodetectors for UV Detection Applications; H. Ghorbel, L. Damé, M. Meftah, X. Arrateig, F. Bouyssou, I. Sidi-Boumeddine, P.Gilbert, P. Maso, D. Rogers, P. Bove, V. Sandana, F. Teherani Proc. of 7th International Conference on Sensors Engineering & Electronics Instrumentation Advances, Mallorca (2021).

Performances and Calibrations of New Disruptive UVC Sensors for New Space Applications; I. Sidi Boumeddine, F. Bouyssou, L. Damé, H. Ghorbel, X. Arrateig, M. Meftah, P.Gilbert, P. Maso, D. Rogers, P. Bove, V. Sandana & F. Teherani; Proc. of 7th International Conference on Sensors Engineering & Electronics Instrumentation Advances, Mallorca (2021).

Development and Simulated Environment Testing of β-(Al) Ga2O3-based Photodetectors for Space-based Observation of the Herzberg Continuum X. Arrateig, D. Rogers, P. Maso, F. Bouyssou, I. Sidi-Boumeddine, W. El-Huni, H. Bouhnane, Y. Sama, P. Bove, S. Le Gall, A. Brezart-Oudot, H. Ghorbel, P. Gilbert, V. Sandana, F. Teherani, S. Gautier, A. Darga, Z. Djebbour, A. Ougazzaden; Proc. of SPIE 11858 (2021) 1185813-1.

Sharp/Tuneable UVC Selectivity and Extreme Solar Blindness in Nominally Undoped Ga2O3 MSM Photodetectors Grown by Pulsed Laser Deposition D. J. Rogers, A. Courtois, F. H. Teherani, V. E. Sandana, P. Bove, X. Arrateig, L. Damé, P. Maso, M. Meftah, W. El Huni, Y. Sama, H. Bouhnane, S. Gautier, A. Ougazzaden & M. Razeghi; Proc. SPIE 11687 (2021) 116872D-1.

A Walk on the Frontier of Energy Electronics with Power Ultra-Wide Bandgap Oxides and Ultra-Thin Neuromorphic 2D Materials A. Pérez-Tomás, E. Chikoizde, D. Rogers, J. A. Garrido; Proc. SPIE 11687 (2021) 116871Y-1.

UVSQ-SAT, a Pathfinder CubeSat Mission for Observing Essential Climate Variables M. Meftah, L. Damé, P. Keckhut, S. Bekki, A. Sarkissian, A. Hauchecorne, E. Bertran, J-P Carta, D. Rogers, S. Abbaki, C. Dufour, P. Gilbert, L. Lapauw, A-J Vieau, X. Arrateig, N. Muscat, P. Bove, É. Sandana, F. Teherani, T. Li, G. Pradel, M. Mahé, C. Mercier, A. Paskeviciute, K. Segura, A. B. Alba, A. Aboulila, L. Chang, A. Chandran, P-R. Dahoo and A. Bui; Remote Sens. 12, (2020) 92.

Red Luminescence in H-doped β-Ga2O3 T. T. Huynh, E. Chikoidze, M. Zakria, Y. Dumont, F. H. Teherani, E. V. Sandana, P. Bove, D. J. Rogers, M. R. Phillips, C. Ton-That; Phys. Rev. Materials 4, 085201 (2020).

Solar-blind Conducting Gallium Oxide Enables Record Bulk Photovoltaic Effect A. Perez-Tomas, E. Chikoidze, Y. Dumont, M. R. Jennings, Y. Kurtuluş, G. Catalana, M. Lira-Cantu, C. Ton-That, F. H. Teherani, V. E. Sandana, P. Bove, and D. J. Rogers; Materials Today Energy, 14 (2019) 100350.

Puzzling Robust 2D Metallic Conductivity in Undoped Beta-Ga2O3 Thin Films E. Chikoidze, D. J. Rogers, F. H. Teherani, C. Rubio, G. Sauthier, H. Von Bardeleben, T. Tchelidze, C. Ton-That, A. Fellous, P. Bove, E. Sandana, Y. Dumont & A. P. Tomas; Materials Today Physics 8 (2019) 10-17.

Wide and Ultra-Wide Bandgap Oxides: Where Paradigm-Shift Photovoltaics Meets Transparent Power Electronics A. Pérez-Tomás, E. Chikoidze, M. R. Jennings, S. A. O. Russell, F. H. Teherani, P. Bove, E. V. Sandana, and D. J. Rogers; Proc. of SPIE 10533 (2018) 105331Q-1.

A Review of the Growth, Doping & Applications of Beta-Ga2O3 Thin Films M. Razeghi, J.-H. Park, R. McClintock, D. Pavlidis, F. H. Teherani, D. J. Rogers, B. A. Magill, G. A. Khodaparast, Y. Xu, J. Wu, and V. P. Dravid; Proc. of SPIE 10533 (2018) 105330R-1.

The New Oxide Paradigm for Solid State Ultraviolet Photodetectors D. J. Rogers, F. H. Teherani, V. E. Sandana, X. Arrateig, P. Bove, M. Razeghi, R. McClintock, E. Frisch, and S. Harel; Proc. of SPIE 10533 (2018) 105331P-1.

A Study into the Impact of Sapphire Substrate Orientation on the Properties of Nominally-Undoped Ga2O3 Thin Films Grown by Pulsed Laser Deposition F. H. Teherani, D. J. Rogers, V. E. Sandana, P. Bove, C. Ton-That, L. L. C. Lem, E. Chikoidze, M. Neumann-Spallart, Y. Dumont, T. Huynh, M. R. Phillips, P. Chapon, R. Mcclintock, & M. Razeghi.

1. Metal-Semiconductor-Metal (MSM) UVC photodetector based on Ga2O3 semiconductor with metallic contacts made of Ni and/or Au and/or Ti, wherein the inclusion of aluminum alloyed with Ga2O3, resulting in a broadened and/or shifted spectral response toward shorter wavelengths compared to a Ga2O3-only based detector.

2. The MSM UVC photodetector with metallic contacts according to claim 1, wherein the trapping of charge holes at the metal-semiconductor interface, increasing the gain, and benefiting from low dark current, fast response, and high photoconductive gain.

3. The MSM UVC photodetectors according to claim 1, wherein it is designed on a substrate that is transparent in the UVC with back-illumination to facilitate the manufacturing of flip-chip devices for higher efficiency compared to front-illuminated detectors.

4. The MSM UVC photodetectors according to claim 1, wherein the said (Al)Ga2O3-based photodetector has a decreasing aluminum concentration gradient through the thickness, created by deposition conditions such as an aluminum flux in MBE, an aluminum precursor flux in MOCVD, or high deposition/annealing temperature/duration that promotes aluminum diffusion from the Al2O3 (sapphire) substrate, enabling the capture of a broader spectrum of UVC light.

5. The flip-chip MSM UVC photodetector according to claim 3, wherein a thin layer between 2 nanometers and 1 micron in thickness of (Al)Ga2O3, with a decreasing aluminum gradient through its thickness, allowing less deep UVC light to transmit further into the layer, reaching closer to the top surface with metallic contacts, providing wide-band UVC detection.

6. An imaging system based on a UVC focal plane array comprising a network of MSM photodetectors according to claim 15, for the remote detection/location/imaging of a fire, corona discharge, missile launch, ozone hole monitoring, or gas detection.
